(19) United States
(12) Patent Application Publication
(10) Pub. No.: US 2025/0142873 A1
(43) Pub. Date: May 1, 2025

(54) Depletion Type Vertical Discrete NMOS Device and Manufacturing Method Thereof

(71) Applicant: Richtek Technology Corporation, Zhubei City (TW)

(72) Inventors: Wu-Te Weng, Hsinchu (TW); Yi-Rong Tu, Taipei (TW); Ying-Shiou Lin, Hsinchu (TW); Yong-Zhong Hu, Hsinchu (TW)

(21) Appl. No.: 18/435,550

(22) Filed: Feb. 7, 2024

(30) Foreign Application Priority Data
Oct. 31, 2023 (TW) 112141874

(51) Int. Cl. H01L 29/78; H01L 21/265; H01L 29/40; H01L 29/66

(52) U.S. Cl. CPC H10D 30/63; H01L 21/26513; H01L 21/26586; H10D 30/025; H10D 64/111

(57) ABSTRACT

A depletion type vertical discrete NMOS device includes: an N-type epitaxial layer formed on an N-type substrate, wherein the N-type epitaxial layer has a top surface and a bottom surface opposite to each other; a P-type well formed in the N-type epitaxial layer; a gate formed outside and connected with the N-type epitaxial layer; an N-type source formed in the N-type epitaxial layer and in contact with the P-type well; an N-type drain including a part of the N-type substrate, which is formed outside and under the N-type epitaxial layer; and an N-type region formed and connected between the P-type well and the gate, which provides a channel, such that the N-type source and the N-type drain are electrically connected with each other during conduction operation, whereas, the N-type source and the N-type drain are electrically disconnected from each other during non-conduction operation.

### CROSS REFERENCE

The present invention priority to TW patent application No. 112141874, filed on Oct. 31, 2023.

### BACKGROUND OF THE INVENTION

### Field of Invention

The present invention relates to a depletion type vertical discrete NMOS device and a manufacturing method thereof; particularly, it relates to a depletion type vertical discrete NMOS device having a wider application scope and a manufacturing method thereof.

### Description of Related Art

In a prior art enhancement type NMOS device, when the gate voltage is zero or negative, its source and drain are not conductive with each other. When a positive gate voltage is applied on the gate of the prior art enhancement type NMOS device, an electron channel is formed between its source and drain, whereby the enhancement type NMOS device turns into a conduction state. The prior art enhancement type NMOS device has a disadvantage that it requires a certain positive level of the gate voltage for the enhancement type NMOS device to be turned ON; therefore, the prior art enhancement type NMOS device cannot be used in applications wherein only low gate voltage can be provided, limiting the application scope for the prior art enhancement type NMOS device.

In view of the above, to overcome the disadvantage of limited application scope of the prior art, the present invention proposes a depletion type vertical discrete NMOS device and a manufacturing method thereof. As compared to the prior art, the present invention is advantageous in that: the present invention is applicable in low gate voltage application and high power application, etc., and, the present invention further has merits of low leakage current and low energy loss.

### SUMMARY OF THE INVENTION

From one perspective, the present invention provides a depletion type vertical discrete NMOS device comprising: an N-type epitaxial layer, which is formed on an N-type substrate, wherein the N-type epitaxial layer has a top surface and a bottom surface which are opposite to each other; a P-type well, which is formed in the N-type epitaxial layer; a gate, which is formed outside and connected with the N-type epitaxial layer; an N-type source, which is formed in the N-type epitaxial layer, wherein the N-type source is within and in contact with the P-type well; an N-type drain including a part of the N-type substrate, wherein the N-type drain is outside and under the N-type epitaxial layer; and an N-type region, which is connected between the P-type well and the gate, wherein the N-type region provides a channel, such that the N-type source and the N-type drain are electrically connected with each other through the channel during conduction operation, whereas, the N-type source and the N-type drain are electrically disconnected from each other during non-conduction operation; wherein when a gate voltage applied on the gate is zero, the depletion type vertical discrete NMOS device is in the conduction operation.

In one embodiment, the depletion type vertical discrete NMOS device is a planar device, wherein the gate is formed on and in contact with the top surface of the N-type epitaxial layer, and wherein the channel is in parallel with the top surface of the N-type epitaxial layer.

In one embodiment, the depletion type vertical discrete NMOS device is a trench device, wherein the gate is formed outside and connected with a side surface of the N-type epitaxial layer, and wherein the channel is in parallel with the side surface of the N-type epitaxial layer and the channel is situated vertically with respect to the top surface of the N-type epitaxial layer.

In one embodiment, the depletion type vertical discrete NMOS device further comprises: a shielding gate, which is formed under the gate and which is connected to the N-type epitaxial layer.

In one embodiment, the N-type substrate is a silicon semiconductor or a silicon carbide semiconductor, or wherein the N-type epitaxial layer is the silicon semiconductor or the silicon carbide semiconductor.

In one embodiment, N-type impurities of the N-type region include one or more elements selected from the group consisting of nitrogen (N), phosphorus (P), arsenic (As), antimony (Sb) and bismuth (Bi).

In one embodiment, the N-type region is formed by an ion implantation process step, wherein an implantation angle of the ion implantation process step lies between 0 degree and 90 degrees.

In one embodiment, a volume resistivity of the N-type epitaxial layer is 45 Ohm-cm.

From another perspective, the present invention provides a manufacturing method of a depletion type vertical discrete NMOS device, comprising following steps: forming an N-type epitaxial layer on an N-type substrate, wherein the N-type epitaxial layer has a top surface and a bottom surface which are opposite to each other; forming a P-type well in the N-type epitaxial layer; forming a gate outside and connected to the N-type epitaxial layer; forming an N-type source in the N-type epitaxial layer, wherein the N-type source is within and in contact with the P-type well; forming an N-type drain outside and under the N-type epitaxial layer, wherein the N-type drain includes a part of the N-type substrate; and forming an N-type region which is connected between the P-type well and the gate, wherein the N-type region provides a channel, such that the N-type source and the N-type drain are electrically connected with each other through the channel during conduction operation, whereas, the N-type source and the N-type drain are electrically disconnected from each other during non-conduction operation; wherein when a gate voltage applied on the gate is zero, the depletion type vertical discrete NMOS device is in the conduction operation.

In one embodiment, the manufacturing method further comprises: etching the N-type epitaxial layer, so as to form a trench and the side surface.

In one embodiment, the manufacturing method further comprises: forming a shielding gate which is under the gate and connected to the N-type epitaxial layer.

In one embodiment, the manufacturing method further comprises: forming the N-type region by an ion implantation process step, wherein an implantation angle of the ion implantation process step lies between 0 degree and 90 degrees.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-sectional view of a depletion type vertical discrete NMOS device according to an exemplary embodiment of the present invention.

FIG. 2 shows a cross-sectional view of a depletion type vertical discrete NMOS device according to another exemplary embodiment of the present invention.

FIG. 3 shows a cross-sectional view of a depletion type vertical discrete NMOS device according to yet another exemplary embodiment of the present invention.

FIG. 4A to FIG. 4E show cross-sectional views depicting a manufacturing method for forming a depletion type vertical discrete NMOS device according to an exemplary embodiment of the present invention.

FIG. 5A to FIG. 5E show cross-sectional views depicting a manufacturing method for forming a depletion type vertical discrete NMOS device according to another exemplary embodiment of the present invention.

FIG. 6A to FIG. 6F show cross-sectional views depicting a manufacturing method for forming a depletion type vertical discrete NMOS device according to yet another exemplary embodiment of the present invention.

FIG. 7A to FIG. 7F show cross-sectional views depicting a manufacturing method for forming a depletion type vertical discrete NMOS device according to another exemplary embodiment of the present invention.

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

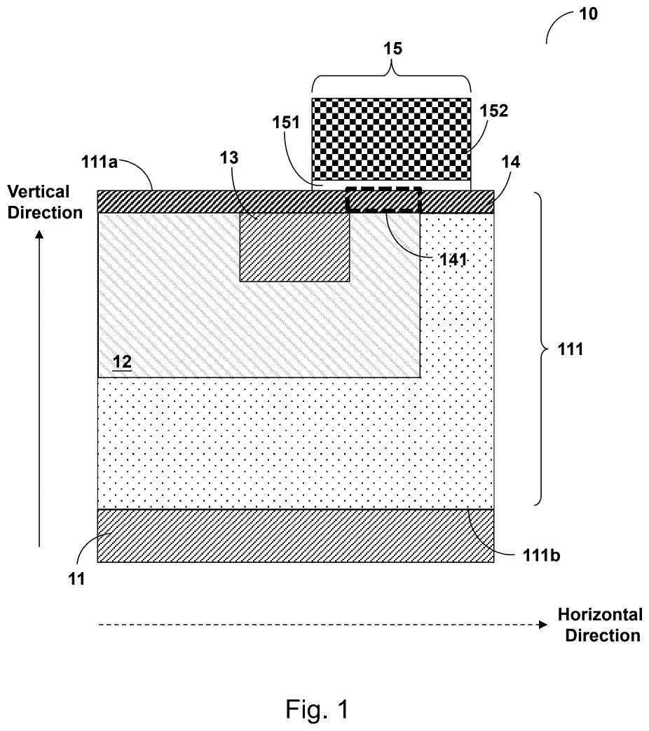

Please refer to FIG. 1, which shows a cross-sectional view of a depletion type vertical discrete NMOS device according to an exemplary embodiment of the present invention. As shown in FIG. 1, in one embodiment, the depletion type vertical discrete NMOS device 10 comprises: an N-type epitaxial layer 111, a P-type well 12, a gate 15, an N-type source 13, an N-type drain and an N-type region 14.

The N-type epitaxial layer 111 is formed on an N-type substrate 11, wherein the N-type epitaxial layer 111 has an N conductivity type. The N-type epitaxial layer 111 has a top surface 111a and a bottom surface 711b that are opposite to each other in a vertical direction (as indicated by the direction of the solid arrow in FIG. 1, and all occurrences of the term “vertical direction” in this specification refer to the same direction). The N-type substrate 11 is, for example but not limited to, an N conductivity type silicon substrate, wherein the N-type epitaxial layer 111 is formed on the N-type substrate 11, for example, by an epitaxial growth process step.

Please still refer to FIG. 1. The P-type well 12 can be formed in the N-type epitaxial layer 111 by, for example, an ion implantation process step, wherein the P-type well 12 has a P conductivity type. The gate 15 is formed outside and connected with the N-type epitaxial layer 111. In this embodiment, the gate 15 includes: a dielectric region 151 and a conductive region 152, wherein the dielectric region 151 is on and is in contact with (i.e., is connected to) the top surface 111a, which is known to a person having ordinary skill in the art, so the details thereof are not redundantly explained here. The N-type source 13 is formed in the N-type epitaxial layer 111 by, for example, an ion implantation process step, wherein the N-type source 13 has an N conductivity type. As shown in FIG. 1, the N-type source 13 is within and connected to the P-type well 12. The N-type drain includes a part of the N-type substrate 11, wherein the N-type drain is connected under the N-type epitaxial layer 111, that is, the N-type drain is connected to the bottom surface 711b. From another perspective, a part of the N-type substrate 11 serves as the N-type drain of the depletion type vertical discrete NMOS device 10.

Please still refer to FIG. 1. The N-type region 14 is formed in the N-type epitaxial layer 111 by, for example, an ion implantation process step, wherein the N-type region 14 is connected between the P-type well 12 and the gate 15. The N-type region 14 is configured to provide a channel 141, such that the N-type source 13 and the N-type drain are electrically connected to each other through the channel 141 during conduction operation, whereas, the N-type source 13 and the N-type drain are electrically disconnected from each other during non-conduction operation. Note that, when the gate voltage applied on the gate 15 is zero, the depletion type vertical discrete NMOS device 10 is in the conduction operation.

In one embodiment, as shown in FIG. 1, the depletion type vertical discrete NMOS device 10 is a planar device, wherein the gate 15 is formed and connected on the top surface 111a of the N-type epitaxial layer 111. The channel 141 is in parallel with the top surface 111a of the N-type epitaxial layer 111.

In one embodiment, the N-type substrate 11 of the depletion type vertical discrete NMOS device 10 is a silicon semiconductor or a silicon carbide semiconductor, whereas, the N-type epitaxial layer 111 of the depletion type vertical discrete NMOS device 10 is a silicon semiconductor or a silicon carbide semiconductor.

In one embodiment, N-type impurities of the N-type region 14 include one or more elements selected from the group consisting of nitrogen (N), phosphorus (P), arsenic (As), antimony (Sb) and bismuth (Bi).

In one embodiment, a volume resistivity of the N-type epitaxial layer 111 is 45 Ohm-cm.

It is worthwhile mentioning that, in the embodiment shown in FIG. 1, as one of average skill in the art readily understands, by describing that “the depletion type vertical discrete NMOS device 10 is a planar device”, it means that the N-type region 14 is distributed on a plain that is parallel with the horizontal direction (which is indicated by the dashed arrow shown in FIG. 1, and all occurrences of the term “horizontal direction” in this specification refer to the same direction), and the channel 141 is in parallel with the top surface 111a.

Note that the gate 15 includes a conductive region 152 which is conductive, and a dielectric region 151 in contact with the top surface 111a. The conductive region 152 serves as an electrical contact of the gate 15, wherein the conductive region 152 is formed on and is in contact with the dielectric region 151, which is known to a person having ordinary skill in the art, so the details thereof are not redundantly explained here.

Note that the above-mentioned “N-type” and “P-type” mean that impurities of corresponding conductivity types are doped in regions of the depletion type vertical discrete NMOS device 10 (for example but not limited to the aforementioned N-type epitaxial layer 111, the aforementioned P-type well 12, the aforementioned gate 15, the aforementioned N-type source 13, the aforementioned N-type drain and the aforementioned N-type region 14, etc.), so that the regions have the corresponding “N-type” or “P-type”, wherein “N-type” is opposite to “P-type”.

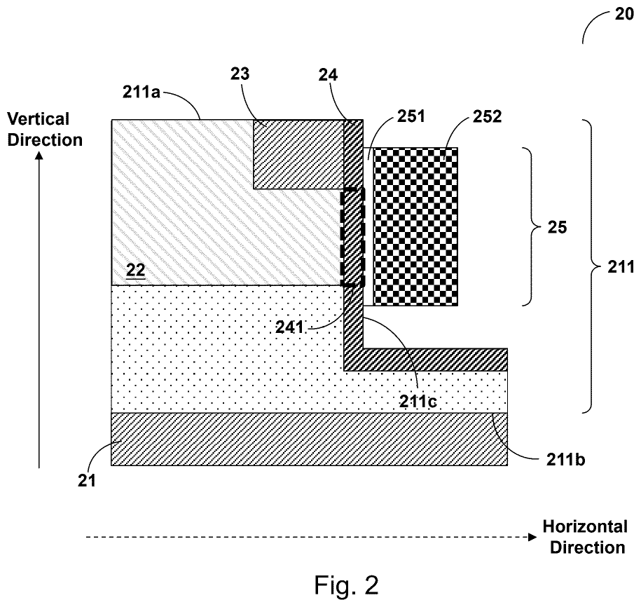

Please refer to FIG. 2, which shows a cross-sectional view of a depletion type vertical discrete NMOS device according to another exemplary embodiment of the present invention. As shown in FIG. 2, in one embodiment, the depletion type vertical discrete NMOS device 20 comprises: an N-type epitaxial layer 211, a P-type well 22, a gate 25, an N-type source 23, an N-type drain and an N-type region 24.

The N-type epitaxial layer 211 is formed on an N-type substrate 21, wherein the N-type epitaxial layer 211 has an N conductivity type. The N-type epitaxial layer 211 has a top surface 211a and a bottom surface 211b which are opposite to each other in a vertical direction (as indicated by the direction of the solid arrow in FIG. 2). The depletion type vertical discrete NMOS device 20 of this embodiment shown in FIG. 2 is different from the depletion type vertical discrete NMOS device 10 in that: the depletion type vertical discrete NMOS device 20 further includes a side surface 211c. The N-type substrate 21 is, for example but not limited to, an N conductivity type silicon substrate, wherein the N-type substrate 21 is formed on the substrate 21, for example, by an epitaxial growth process step.

Please still refer to FIG. 2. The P-type well 22 can be formed in the N-type epitaxial layer 211 by, for example, an ion implantation process step, wherein the P-type well 22 has a P conductivity type. The gate 25 is formed outside and connected with the N-type epitaxial layer 211. In this embodiment, the gate 25 includes: a dielectric region 251 and a conductive region 252, wherein the dielectric region 251 is in contact with the side surface 211c. The N-type source 23 can be formed in the N-type epitaxial layer 211 by, for example, an ion implantation process step, wherein the N-type source 23 has an N conductivity type. As shown in FIG. 2, the N-type source 23 is within and in contact with the P-type well 22. The N-type drain includes a part of the N-type substrate 21, wherein the N-type drain is outside and under the N-type epitaxial layer 211. That is, the N-type drain is under and in contact with the bottom surface 211b. From another perspective, a part of the N-type substrate 21 serves as the N-type drain of the depletion type vertical discrete NMOS device 20.

Please still refer to FIG. 2. The N-type region 24 can be formed in the N-type epitaxial layer 211 by, for example, an ion implantation process step, wherein the N-type region 24 is connected between the P-type well 22 and the gate 25. The N-type region 24 provides a channel 241, such that the N-type source 23 and the N-type drain are electrically connected with each other through the channel 241 during conduction operation, whereas, the N-type source 23 and the N-type drain are electrically disconnected from each other during non-conduction operation. When a gate voltage applied on the gate 25 is zero, the depletion type vertical discrete NMOS device 20 is in the conduction operation.

In one embodiment, as shown in FIG. 2, the depletion type vertical discrete NMOS device 20 is a trench device, wherein the gate 25 is formed on and in contact with the side surface 211c of the N-type epitaxial layer 211. The channel 241 is in parallel with the side surface 211c of the N-type epitaxial layer 211 and the channel 241 is situated vertically with respect to the top surface 211a of the N-type epitaxial layer 211.

In one embodiment, the N-type substrate 21 of the depletion type vertical discrete NMOS device 20 is a silicon semiconductor or a silicon carbide semiconductor, whereas, the N-type epitaxial layer 211 of the depletion type vertical discrete NMOS device 20 is a silicon semiconductor or a silicon carbide semiconductor.

In one embodiment, N-type impurities of the N-type region 24 include one or more elements selected from the group consisting of nitrogen (N), phosphorus (P), arsenic (As), antimony (Sb) and bismuth (Bi).

In one embodiment, a volume resistivity of the N-type epitaxial layer 211 is 45 Ohm-cm.

It is worthwhile mentioning that, in the embodiment shown in FIG. 2, by describing that “the depletion type vertical discrete NMOS device 20 is a trench device”, it means that: in a horizontal direction (as indicated by the direction of the dashed arrow shown in FIG. 2), the N-type epitaxial layer 211 has a recessed trench, and the N-type region 24 is not situated within a plane that is parallel with the aforementioned horizontal direction. Furthermore, the channel 241 is in parallel with the side surface 211c of the N-type epitaxial layer 211 and the channel 241 is situated vertically with respect to the top surface 211a of the N-type epitaxial layer 211.

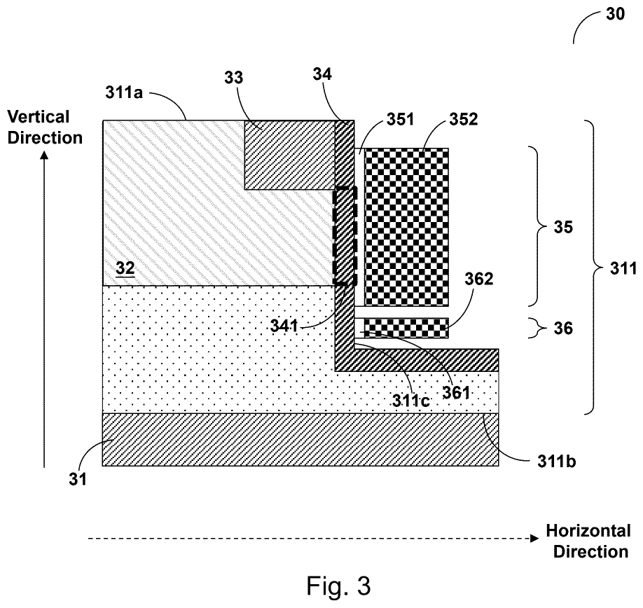

Please refer to FIG. 3, which shows a cross-sectional view of a depletion type vertical discrete NMOS device according to yet another exemplary embodiment of the present invention. The depletion type vertical discrete NMOS device 30 of this embodiment shown in FIG. 3 is similar to the depletion type vertical discrete NMOS device 20 of the embodiment shown in FIG. 2 in that the depletion type vertical discrete NMOS device 30 comprises: an N-type epitaxial layer 311, a P-type well 33, a gate 35, an N-type source 33, an N-type drain an N-type region 34 and an N-type substrate 31, wherein the gate 35 includes: a dielectric region 351 and a conductive region 352. The N-type epitaxial layer 311 has a top surface 311a, a bottom surface 311b and a side surface 311c. The N-type region 34 serves to provide a channel 341. The structural and functional details of the aforementioned components are the same as those in the depletion type vertical discrete NMOS device 20, so the details thereof are not redundantly repeated here; please refer to the relevant descriptions of the embodiment shown in FIG. 2.

However, the depletion type vertical discrete NMOS device 30 of this embodiment shown in FIG. 3 is different from the depletion type vertical discrete NMOS device 20 of the embodiment shown in FIG. 2 in that: the depletion type vertical discrete NMOS device 30 further comprises a shielding gate 36, which is formed under the gate 35 and is connected to the N-type epitaxial layer 311. The shielding gate 36 includes a dielectric region 361 and a conductive region 362, wherein the dielectric region 361 is in contact with the side surface 311c. The shielding gate 36 serves to mitigate the electric field coupling effect between the gate 35 and the channel 341, so as to enhance the performance of the depletion type vertical discrete NMOS device 30. It is noteworthy mentioning that, the shielding gate 36 is separated from the gate 35, namely, the shielding gate 36 is not directly connected to the gate 35 and the shielding gate 36 is not electrically connected to the gate 35.

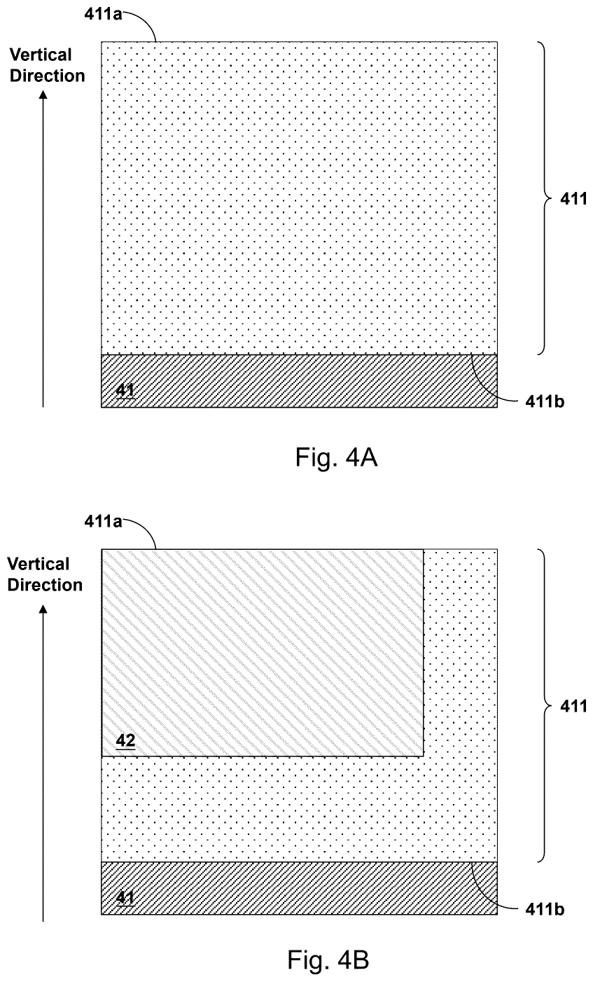

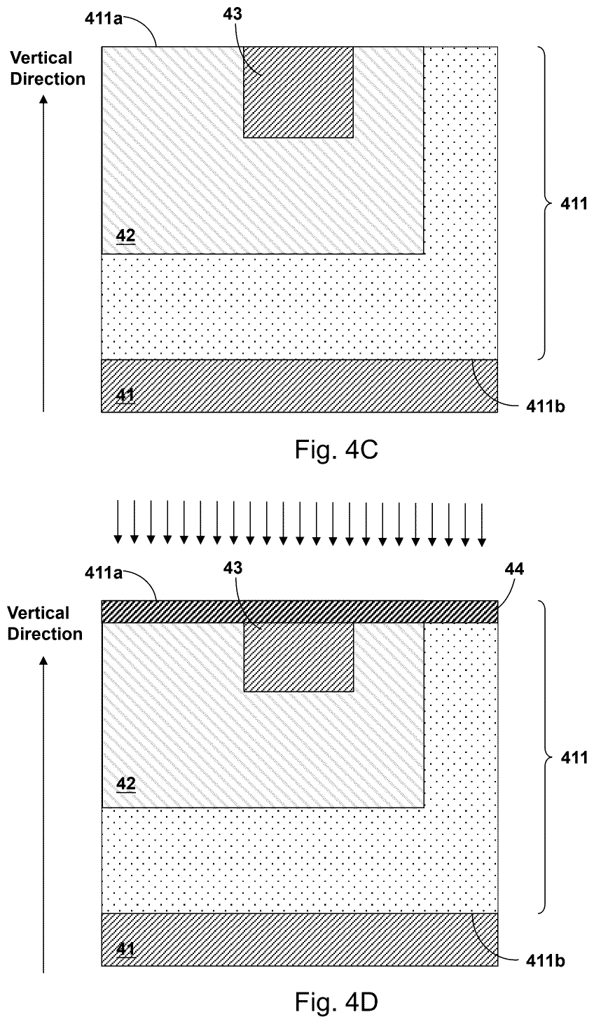

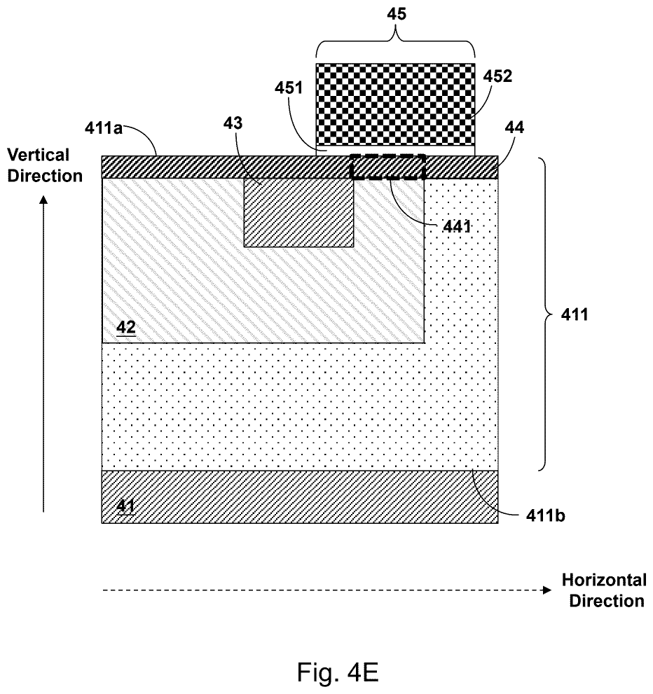

Please refer to FIG. 4A to FIG. 4E, which show cross-sectional views depicting a manufacturing method for forming a depletion type vertical discrete NMOS device according to an exemplary embodiment of the present invention. FIG. 4A to FIG. 4E show a manufacturing method for forming the depletion type vertical discrete NMOS device 10 shown in FIG. 1. As shown in FIG. 4A, first, an N-type substrate 41 is provided. Next, an N-type epitaxial layer 411 is formed on the N-type substrate 41 by, for example but not limited to, an epitaxial growth process step. The N-type epitaxial layer 411 has a top surface 411a and a bottom surface 411b which are opposite to each other in a vertical direction. Next, an N-type drain is formed outside and under the N-type epitaxial layer 411, wherein the N-type drain including a part of the N-type substrate 41. That is, from another perspective, a part of the N-type substrate 41 serves as the N-type drain of the depletion type vertical discrete NMOS device 10.

Next, referring to FIG. 4B, a P-type well 42 is formed in the N-type epitaxial layer 411 by, for example, an ion implantation process step. In this embodiment, to be more specific, the P-type well 42 can be formed by, for example, an ion implantation process step which implants P-conductivity type impurities under the top surface 411a of the N-type epitaxial layer 411, wherein the implanted region is connected to the top surface 411a. After an N-type region 44 is formed by a following process step (the details of which will be described later with reference to FIG. 4D), the implanted N conductivity type impurities having a relatively higher concentration will counter-dope the P conductivity type impurities having a relatively lower concentration, whereby the semiconductor region having the P conductivity type will be transformed into a semiconductor region having the N conductivity type, which is well known to a person having ordinary skill in the art, so the details thereof are not redundantly explained here. Next, referring to FIG. 4C, an N-type source 43 is formed in the N-type epitaxial layer 411 by, for example, an ion implantation process step, wherein the formed N-type source 43 is within and in contact with the P-type well 42. Next, referring to FIG. 4D, an N-type region 44 is formed in the N-type epitaxial layer 111 by, for example, an ion implantation process step, wherein the N-type region 44 is connected to the P-type well 42. Next, referring to FIG. 4E, a gate 45 is formed outside and connected with the N-type epitaxial layer 411. In this embodiment, the gate 45 includes a dielectric region 451 and a conductive region 452, wherein the dielectric region 451 is on and is in contact with (i.e., is connected to) the top surface 411a.

It is worthwhile mentioning that, in the aforementioned ion implantation process step that is adopted to form the N-type region 44, the implantation angle of this ion implantation process step lies between 0 degree and 90 degrees. In this embodiment, the implantation angle for forming the N-type region 44 is 0 degree. The “implantation angle” refers to: an angle between a forward direction of the ion beam in the ion implantation process step and a normal line direction of the channel 441.

Please still refer to FIG. 4E. The N-type region 44 is connected between the P-type well 42 and the gate 45. The N-type region 44 provides a channel 441, such that the N-type source 43 and the N-type drain are electrically connected with each other through the channel 441 during conduction operation, whereas, the N-type source 43 and the N-type drain are electrically disconnected from each other during non-conduction operation.

It is worthwhile mentioning that, the depletion type vertical discrete NMOS device 10 manufactured by the manufacturing method according to the embodiment of FIG. 4A to FIG. 4E, is a planar device. That is, the gate 45 is formed on and in contact with the top surface 411a of the N-type epitaxial layer 411. The N-type region 44 is in a plane which is in parallel with the aforementioned horizontal direction. The channel 441 is in parallel with the top surface 411a of the N-type epitaxial layer 411.

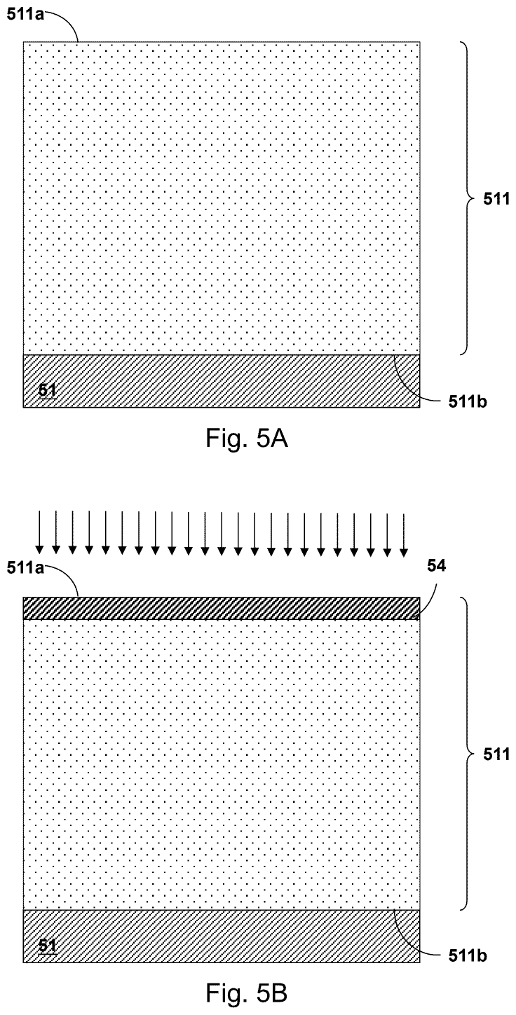

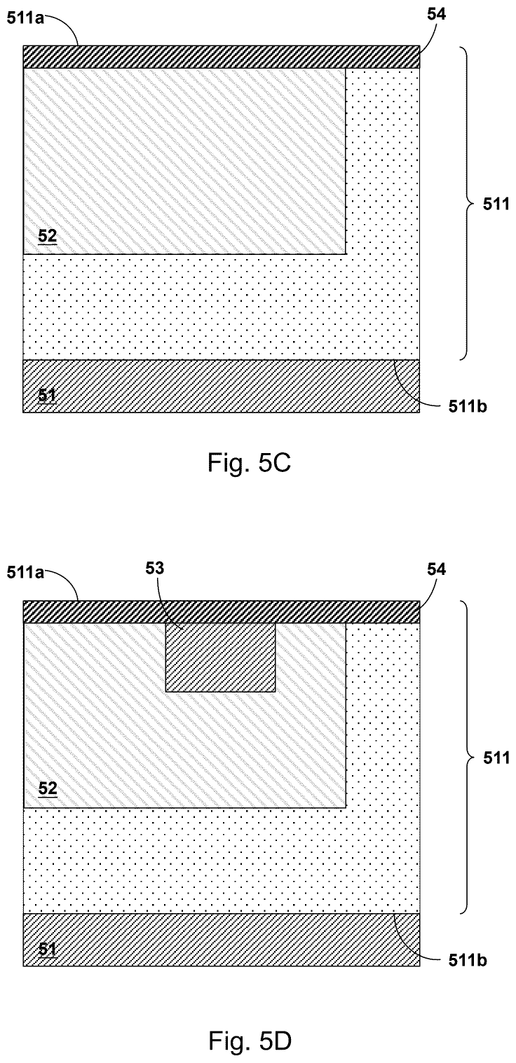

Please refer to FIG. 5A to FIG. 5E, which show cross-sectional views depicting a manufacturing method for forming a depletion type vertical e NMOS device according to another exemplary embodiment of the present invention. FIG. 5A to FIG. 5E show a manufacturing method for forming the depletion type vertical discrete NMOS device 10 shown in FIG. 1 according to another exemplary embodiment of the present invention. As shown in FIG. 5A, first, an N-type substrate 41 is provided. Next, an N-type epitaxial layer 511 is formed on the N-type substrate 51 by, for example but not limited to, an epitaxial growth process step. The N-type epitaxial layer 511 has a top surface 511a and a bottom surface 511b which are opposite to each other in a vertical direction. Next, an N-type drain is formed outside and under the N-type epitaxial layer 511, wherein the N-type drain includes a part of the N-type substrate 51. That is, from another perspective, a part of the N-type substrate 51 serves as the N-type drain of the depletion type vertical discrete NMOS device 10.

Next, referring to FIG. 5B, an N-type region 54 is formed in the N-type epitaxial layer 511 by, for example, an ion implantation process step. Next, referring to FIG. 5C, a P-type well 52 is formed in the N-type epitaxial layer 511 by, for example, an ion implantation process step, and the N-type region 54 in connected with the P-type well 52. Next, referring to FIG. 5D, an N-type source 53 is formed in the N-type epitaxial layer 511 by, for example, an ion implantation process step, wherein the N-type source 53 is within and in contact with the P-type well 52. Next, referring to FIG. 5E, a gate 55 is formed outside and connected with the N-type epitaxial layer 511. In this embodiment, the gate 55 includes: a dielectric region 551 and a conductive region 552, wherein the dielectric region 551 is on and is in contact with (i.e., is connected to) the top surface 511a.

It is worthwhile mentioning that, in the aforementioned ion implantation process step that is adopted to form the N-type region 54, the implantation angle adopted by this ion implantation process step lies between 0 degree and 90 degrees. In this embodiment, the implantation angle for forming the N-type region 54 is 0 degree.

Please still refer to FIG. 5E. The N-type region 54 is connected between the P-type well 52 and the gate 55. The N-type region 54 provides a channel 541, such that the N-type source 53 and the N-type drain are electrically connected with each other through the channel 541 during conduction operation, whereas, the N-type source 53 and the N-type drain are electrically disconnected from each other during non-conduction operation.

It is worthwhile mentioning that, the depletion type vertical discrete NMOS device 10 manufactured by the manufacturing method according to the embodiment of FIG. 5A to FIG. 5E, is a planar device. That is, the gate 55 is formed on and in contact with the top surface 511a of the N-type epitaxial layer 511. The N-type region 54 is in a plane which is in parallel with the aforementioned horizontal direction. The channel 541 is in parallel with the top surface 511a of the N-type epitaxial layer 511.

It is worthwhile mentioning that, the depletion type vertical discrete NMOS device 10 of the embodiment shown in FIG. 1 can be manufactured by the manufacturing method of the embodiment shown in FIG. 4A to FIG. 4E or by the manufacturing method of the embodiment shown in FIG. 5A to FIG. 5E.

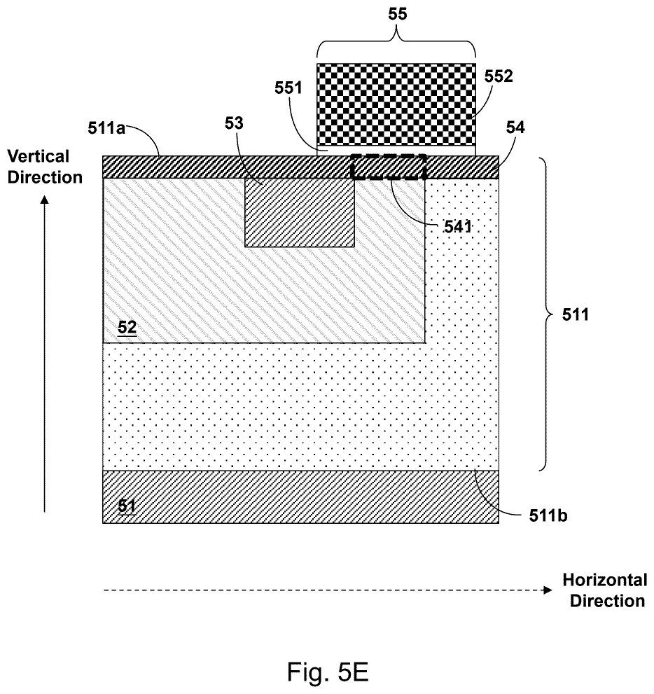

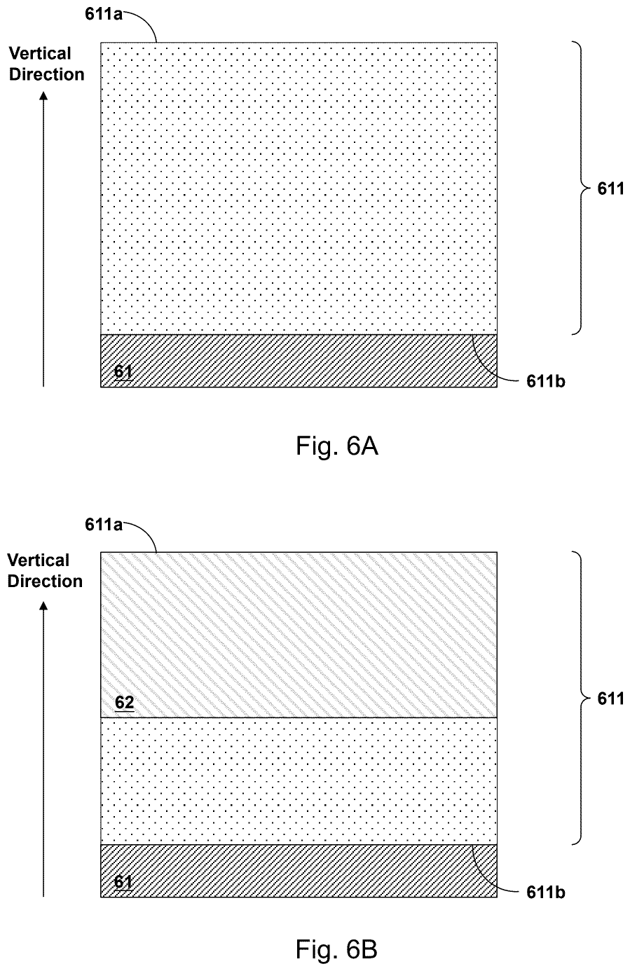

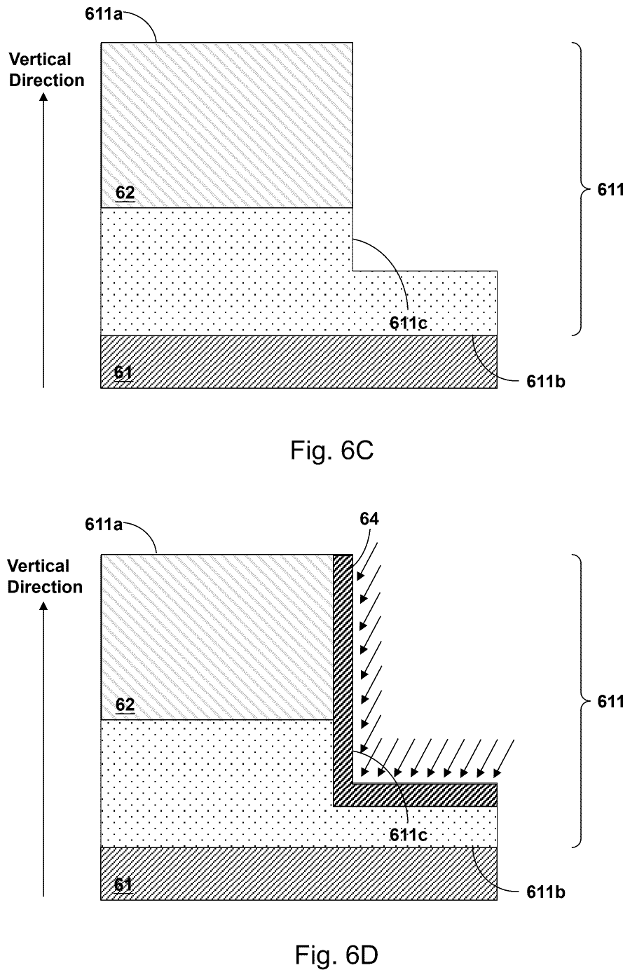

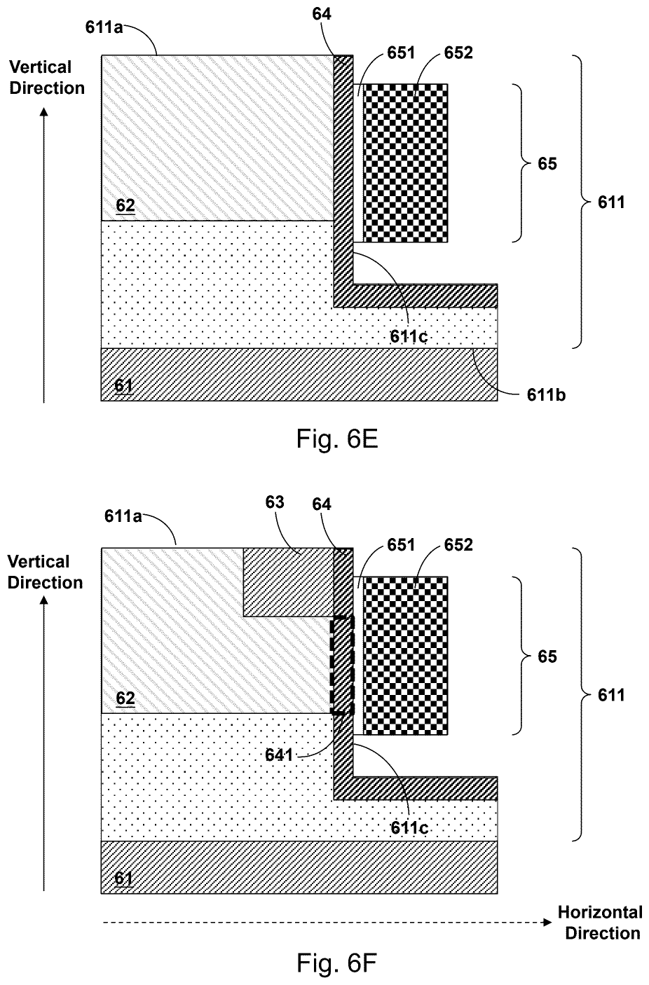

Please refer to FIG. 6A to FIG. 6F, which show cross-sectional views depicting a manufacturing method for forming a depletion type vertical discrete NMOS device according to yet another exemplary embodiment of the present invention. FIG. 6A to FIG. 6F show a manufacturing method for forming the depletion type vertical discrete NMOS device 20 shown in FIG. 2. As shown in FIG. 6A, first, an N-type substrate 61 is provided. Next, an N-type epitaxial layer 611 is formed on the N-type substrate 61 by, for example but not limited to, an epitaxial growth process step. The N-type epitaxial layer 611 has a top surface 611a and a bottom surface 611b which are opposite to each other in a vertical direction. Next, an N-type drain is formed outside and under the N-type epitaxial layer 611, wherein the N-type drain includes a part of the N-type substrate 61. That is, from another perspective, a part of the N-type substrate 61 serves as the N-type drain of the depletion type vertical discrete NMOS device 20.

Next, referring to FIG. 6B, the P-type well 62 is formed in the N-type epitaxial layer 611 by, for example, an ion implantation process step. Next, referring to FIG. 4C, the N-type epitaxial layer 611 is etched in a vertical direction, (wherein a part of the P-type well 62 is also etched), so as to form a trench and the side surface 611c. Next, referring to FIG. 6D, an N-type region 64 is formed by, for example, an ion implantation process step, wherein the N-type region 64 is connected to the P-type well 62 and the N-type epitaxial layer 611. Next, referring to FIG. 6E, a gate 65 is formed outside and connected with the N-type epitaxial layer 611. In this embodiment, the gate 65 includes: a dielectric region 651 and a conductive region 652, wherein the dielectric region 651 is on and is in contact with (i.e., is connected to) the side surface 611c. Next, referring to FIG. 6F, an N-type source 63 is formed in the N-type epitaxial layer 611 by, for example, an ion implantation process step, wherein the N-type source 63 is within and in contact with the P-type well 62.

It is worthwhile mentioning that, in the aforementioned ion implantation process step that is adopted to form the N-type region 64, the implantation angle adopted by this ion implantation process step lies between 0 degree and 90 degrees.

Please still refer to FIG. 6F. The N-type region 64 provides a channel 641, such that the N-type source 63 and the N-type drain are electrically connected with each other through the channel 641 during conduction operation, whereas, the N-type source 63 and the N-type drain are electrically disconnected from each other during non-conduction operation.

It is worthwhile mentioning that, the depletion type vertical discrete NMOS device 20 manufactured by the manufacturing method according to the embodiment of FIG. 6A to FIG. 6F, is a trench device. That is, the gate 65 is formed outside and is connected with the side surface 611c of the N-type epitaxial layer 611. In a horizontal direction (as indicated by the direction of the dashed arrow shown in FIG. 6F), the N-type epitaxial layer 611 has a recessed trench. Besides, the N-type region 64 is not situated within a plane that is in parallel with the aforementioned horizontal direction; in addition, the channel 641 is in parallel with the side surface 611c of the N-type epitaxial layer 611 and the channel 641 is situated vertically with respect to the top surface 611a of the N-type epitaxial layer 611.

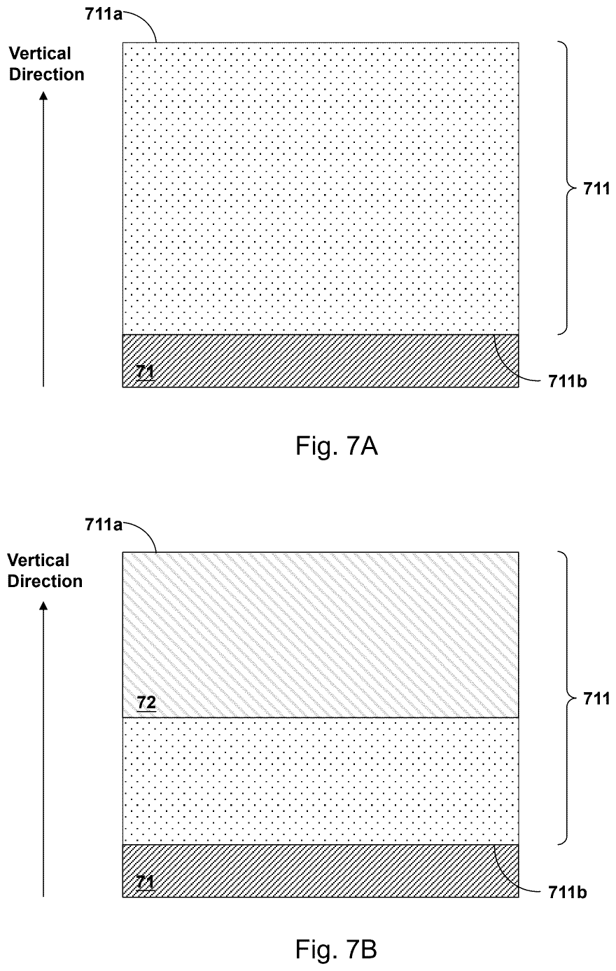

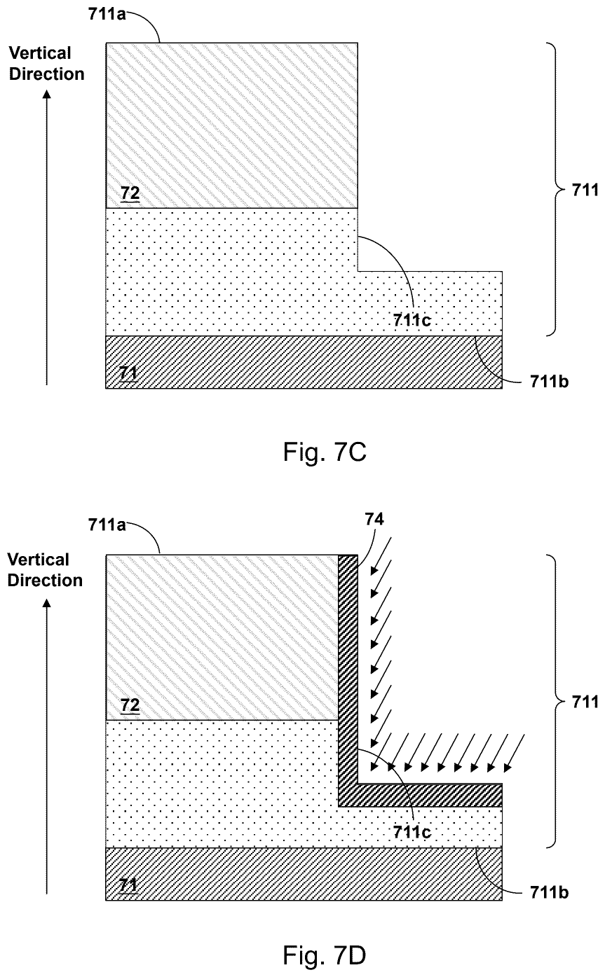

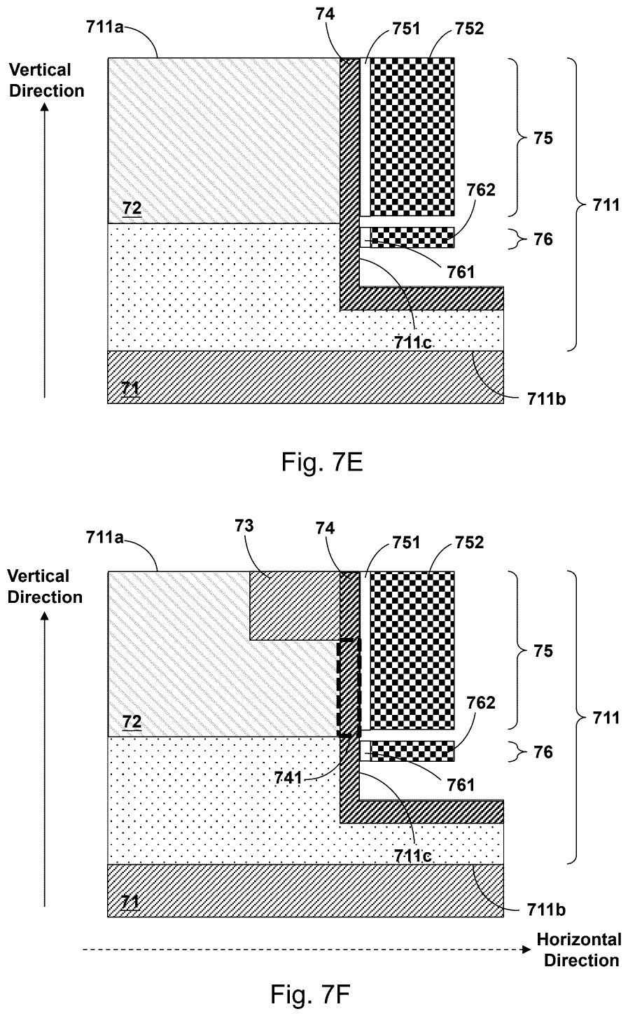

Please refer to FIG. 7A to FIG. 7F, which show cross-sectional views depicting a manufacturing method for forming a depletion type vertical discrete NMOS device according to another exemplary embodiment of the present invention. The steps for forming an N-type substrate 71, an N-type epitaxial layer 711, a top surface 711a of the N-type epitaxial layer 711, a bottom surface 711b of the N-type epitaxial layer 711, a P-type well 72, a side surface 711c of the N-type epitaxial layer 711 and an N-type region 74 are the same as the steps described in the exemplary embodiment shown in FIG. 6A to FIG. 6D, so the details thereof are not repeated here.

Please refer to FIG. 7E. A gate 75 is formed outside and connected with the N-type epitaxial layer 711. In this embodiment, the gate 75 includes: a dielectric region 751 and a conductive region 752, wherein the dielectric region 751 is on and is in contact with (i.e., is connected to) the side surface 711c. Further, different from the embodiment shown in FIG. 6E, in this embodiment, a shielding gate 76 of the depletion type vertical discrete NMOS device 30 is formed under the gate 75 and is connected to the N-type epitaxial layer 711. The shielding gate 76 includes: a dielectric region 761 and a conductive region 762, wherein the dielectric region 761 is in contact with the side surface 711c. Next, referring to FIG. 7F, an N-type source 73 is formed in the N-type epitaxial layer 711 by, for example, an ion implantation process step, wherein the N-type source 73 is within and in contact with the P-type well 72.

Please still refer to FIG. 7F. The N-type region 74 is connected between the P-type well 72 and the gate 75, and the N-type region 74 is connected between the N-type epitaxial layer 711 and the shielding gate 76. The N-type region 74 provides a channel 741, such that the N-type source 73 and the N-type drain are electrically connected with each other through the channel 741 during conduction operation, whereas, the N-type source 73 and the N-type drain are electrically disconnected from each other during non-conduction operation.

It is worthwhile mentioning that, the depletion type vertical discrete NMOS device 30 manufactured by the manufacturing method according to the embodiment of FIG. 7A to FIG. 7F, is a trench device. That is, the gate 75 is formed outside and is connected with the side surface 711c of the N-type epitaxial layer 711. In a horizontal direction (as indicated by the direction of the dashed arrow shown in FIG. 7F), the N-type epitaxial layer 711 has a recessed trench. Besides, the N-type region 74 is not situated within a plane that is in parallel with the aforementioned horizontal direction; in addition, the channel 741 is in parallel with the side surface 711c of the N-type epitaxial layer 711 and the channel 741 is situated vertically with respect to the top surface 711a of the N-type epitaxial layer 711.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography process step is not limited to the mask technology but it can be electron beam lithography. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A depletion type vertical discrete NMOS device comprising:
an N-type epitaxial layer, which is formed on an N-type substrate, wherein the N-type epitaxial layer has a top surface and a bottom surface which are opposite to each other;
a P-type well, which is formed in the N-type epitaxial layer;
a gate, which is formed outside and connected with the N-type epitaxial layer;
an N-type source, which is formed in the N-type epitaxial layer, wherein the N-type source is within and in contact with the P-type well;
an N-type drain including a part of the N-type substrate, wherein the N-type drain is outside and under the N-type epitaxial layer; and
an N-type region, which is connected between the P-type well and the gate, wherein the N-type region provides a channel, such that the N-type source and the N-type drain are electrically connected with each other through the channel during conduction operation, whereas, the N-type source and the N-type drain are electrically disconnected from each other during non-conduction operation;
wherein when a gate voltage applied on the gate is zero, the depletion type vertical discrete NMOS device is in the conduction operation.

2. The depletion type vertical discrete NMOS device as claimed in claim 1, wherein the depletion type vertical discrete NMOS device is a planar device, wherein the gate is formed on and in contact with the top surface of the N-type epitaxial layer, and wherein the channel is in parallel with the top surface of the N-type epitaxial layer.

3. The depletion type vertical discrete NMOS device as claimed in claim 1, wherein the depletion type vertical discrete NMOS device is a trench device, wherein the gate is formed outside and connected with a side surface of the N-type epitaxial layer, and wherein the channel is in parallel with the side surface of the N-type epitaxial layer and the channel is situated vertically with respect to the top surface of the N-type epitaxial layer.

4. The depletion type vertical discrete NMOS device as claimed in claim 3, further comprising:
a shielding gate, which is formed under the gate and which is connected to the N-type epitaxial layer.

5. The depletion type vertical discrete NMOS device as claimed in claim 1, wherein the N-type substrate is a silicon semiconductor or a silicon carbide semiconductor, or wherein the N-type epitaxial layer is the silicon semiconductor or the silicon carbide semiconductor.

6. The depletion type vertical discrete NMOS device as claimed in claim 1, wherein N-type impurities of the N-type region include one or more elements selected from the group consisting of nitrogen (N), phosphorus (P), arsenic (As), antimony (Sb) and bismuth (Bi).

7. The depletion type vertical discrete NMOS device as claimed in claim 1, wherein the N-type region is formed by an ion implantation process step, wherein an implantation angle of the ion implantation process step lies between 0 degree and 90 degrees.

8. The depletion type vertical discrete NMOS device as claimed in claim 1, wherein a volume resistivity of the N-type epitaxial layer is 45 Ohm-cm.

9. A manufacturing method of a depletion type vertical discrete NMOS device, comprising following steps:
forming an N-type epitaxial layer on an N-type substrate, wherein the N-type epitaxial layer has a top surface and a bottom surface which are opposite to each other;
forming a P-type well in the N-type epitaxial layer;
forming a gate outside and connected to the N-type epitaxial layer;
forming an N-type source in the N-type epitaxial layer, wherein the N-type source is within and in contact with the P-type well;
forming an N-type drain outside and under the N-type epitaxial layer, wherein the N-type drain includes a part of the N-type substrate; and
forming an N-type region which is connected between the P-type well and the gate, wherein the N-type region provides a channel, such that the N-type source and the N-type drain are electrically connected with each other through the channel during conduction operation, whereas, the N-type source and the N-type drain are electrically disconnected from each other during non-conduction operation;
wherein when a gate voltage applied on the gate is zero, the depletion type vertical discrete NMOS device is in the conduction operation.

10. The manufacturing method as claimed in claim 9, wherein the depletion type vertical discrete NMOS device is a planar device, wherein the gate is formed on and in contact with the top surface of the N-type epitaxial layer, and wherein the channel is in parallel with the top surface of the N-type epitaxial layer.

11. The manufacturing method as claimed in claim 9, wherein the depletion type vertical discrete NMOS device is a trench device, wherein the gate is formed outside and connected with a side surface of the N-type epitaxial layer, and wherein the channel is in parallel with the side surface of the N-type epitaxial layer and the channel is situated vertically with respect to the top surface of the N-type epitaxial layer.

12. The manufacturing method as claimed in claim 11, further comprising:
etching the N-type epitaxial layer, so as to form a trench and the side surface.

13. The manufacturing method as claimed in claim 11, further comprising:
forming a shielding gate which is under the gate and connected to the N-type epitaxial layer.

14. The manufacturing method as claimed in claim 9, wherein the N-type substrate is a silicon semiconductor or a silicon carbide semiconductor, or wherein the N-type epitaxial layer is the silicon semiconductor or the silicon carbide semiconductor.

15. The manufacturing method as claimed in claim 9, wherein N-type impurities of the N-type region include one or more elements selected from the group consisting of nitrogen (N), phosphorus (P), arsenic (As), antimony (Sb) and bismuth (Bi).

16. The manufacturing method as claimed in claim 9, further comprising following step:
forming the N-type region by an ion implantation process step, wherein an implantation angle of the ion implantation process step lies between 0 degree and 90 degrees.

17. The manufacturing method as claimed in claim 9, wherein a volume resistivity of the N-type epitaxial layer is 45 Ohm-cm.
